(19) United States
(12) Patent Application Publication
(10) Pub. No.: US 2015/0008021 A1
(43) Pub. Date: Jan. 8, 2015

(54) PRINTED WIRING BOARD AND METHOD FOR MANUFACTURING PRINTED WIRING BOARD

(71) Applicant: IBIDEN CO., LTD., Ogaki-shi (JP)

(72) Inventors: Naoto Ishida, Ogaki-shi (JP); Kota Noda, Ogaki-shi (JP)

(73) Assignee: IBIDEN CO., LTD., Ogaki-shi (JP)

(21) Appl. No.: 14/316,966

(22) Filed: Jun. 27, 2014

(30) Foreign Application Priority Data
Jul. 3, 2013 (JP) 2013-139937

(51) Int. Cl. H05K 1/03; H05K 1/11; H05K 3/40; H05K 1/09

(52) U.S. Cl. CPC H05K 1/0306; H05K 1/09; H05K 1/111; H05K 3/4015
USPC 174/257; 174/258; 216/20

(57) ABSTRACT

A printed wiring board includes an interlayer resin insulation layer, multiple pads formed on the interlayer resin insulation layer, and multiple metal posts having bonding material portions and positioned on the pads, respectively, such that the metal posts are bonded to the pads through the bonding material portions of the metal posts, respectively.

### CROSS-REFERENCE TO RELATED APPLICATIONS

The present application is based upon and claims the benefit of priority to Japanese Patent Application No. 2013-139937, filed Jul. 3, 2013, the entire contents of which are incorporated herein by reference.

### BACKGROUND OF THE INVENTION

1. Field of the Invention

The present invention relates to a printed wiring board having metal posts for mounting another printed wiring board, and to a method for manufacturing such a printed wiring board.

2. Description of Background Art

US2010/0270067 A1 describes a method for forming metal posts on pads provided in a printed wiring board. Metal posts in US2010/0270067 A1 are formed on a printed wiring board by a plating process. The entire contents of this publication are incorporated herein by reference.

### SUMMARY OF THE INVENTION

According to one aspect of the present invention, a printed wiring board includes an interlayer resin insulation layer, multiple pads formed on the interlayer resin insulation layer, and multiple metal posts having bonding material portions and positioned on the pads, respectively, such that the metal posts are bonded to the pads through the bonding material portions of the metal posts, respectively.

According to another aspect of the present invention, a method for manufacturing a printed wiring board includes forming a metal layer on a support film, forming a bonding layer on the metal layer, etching the bonding layer such that the bonding layer is selectively removed and multiple bonding material portions are formed on the metal layer, etching the metal layer such that the metal layer is selectively removed and multiple metal posts having the bonding material portions respectively are formed on the support film, positioning the metal posts having the bonding material portions onto pads formed on a printed wiring board such that the bonding material portions face the pads, respectively, and bonding the metal posts to the pads through the bonding material portions of the metal posts.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing an application example of a printed wiring board according to a first embodiment of the present invention;

FIG. 2 is a view showing a step in manufacturing a printed wiring board according to the first embodiment;

FIG. 3(A)-3(B) are views showing steps in manufacturing a printed wiring board according to the first embodiment;

FIG. 4(A) is a cross-sectional view of the printed wiring board according to the first embodiment, and 4(B) is an example of a metal post;

FIG. 5(A) is a plan view of a mounting surface, 5(B) is a view showing a mounting surface with metal posts, and 5(C) is a plan view showing a support film and metal posts;

FIG. 6(A)-6(E) are views showing steps in manufacturing metal posts of a printed wiring board according to the first embodiment;

FIG. 7(A)-7(D) are views showing steps in manufacturing metal posts of a printed wiring board according to the first embodiment;

FIG. 8 is a cross-sectional view of a printed wiring board according to a second embodiment of the present invention;

FIG. 9(A)-9(C) are views showing steps in manufacturing metal posts of a printed wiring board according to the second embodiment;

FIG. 10(A)-10(C) are views showing steps in manufacturing metal posts of a printed wiring board according to the second embodiment;

FIG. 11 is a view showing steps in manufacturing a printed wiring board according to the second embodiment;

FIG. 12 is a plan view showing a support film and a metal layer of the second embodiment;

FIG. 13 is a cross-sectional view showing an application example of a printed wiring board according to the second embodiment;

FIG. 14(A)-14(D) are: views showing steps in manufacturing metal posts in another example; and

FIG. 15 is a cross-sectional view of a printed wiring board according to a third embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

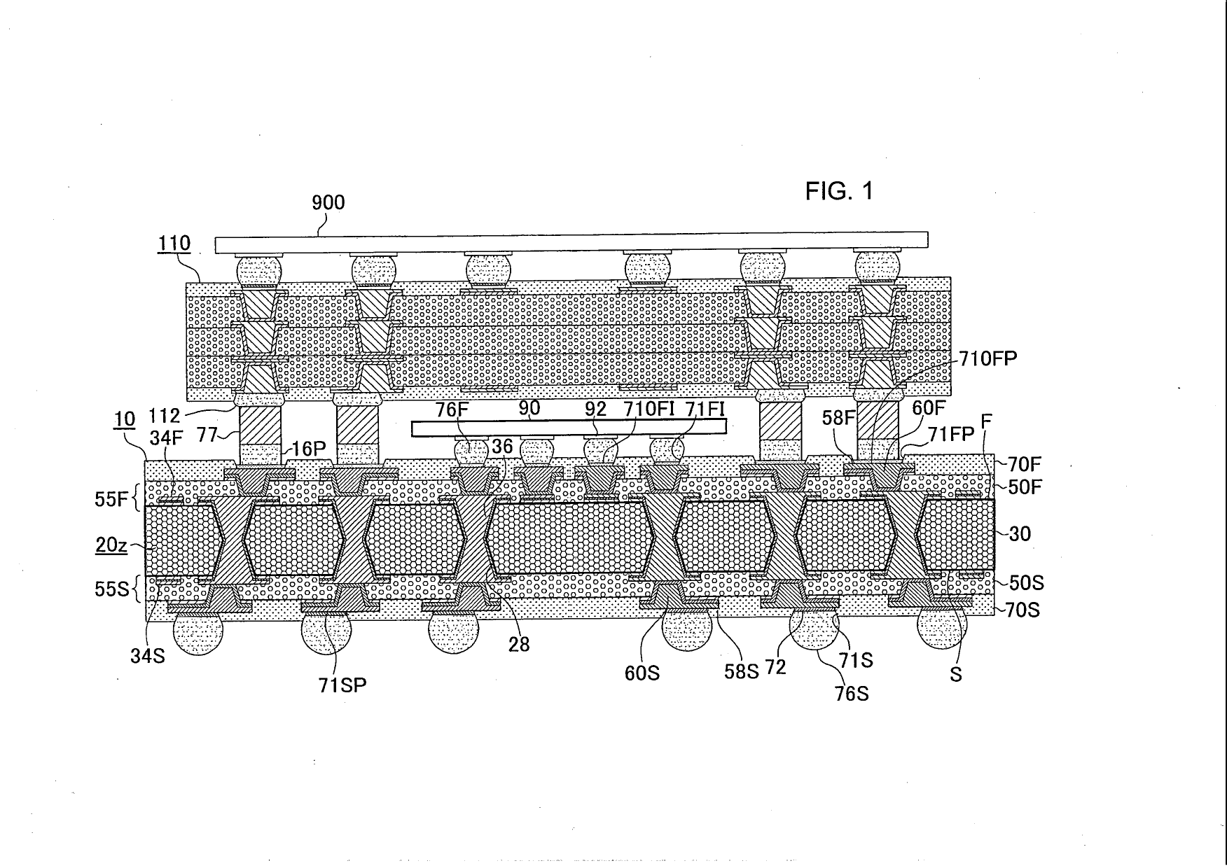

FIG. 1 shows an application example of printed wiring board 10 according to a first embodiment of the present invention.

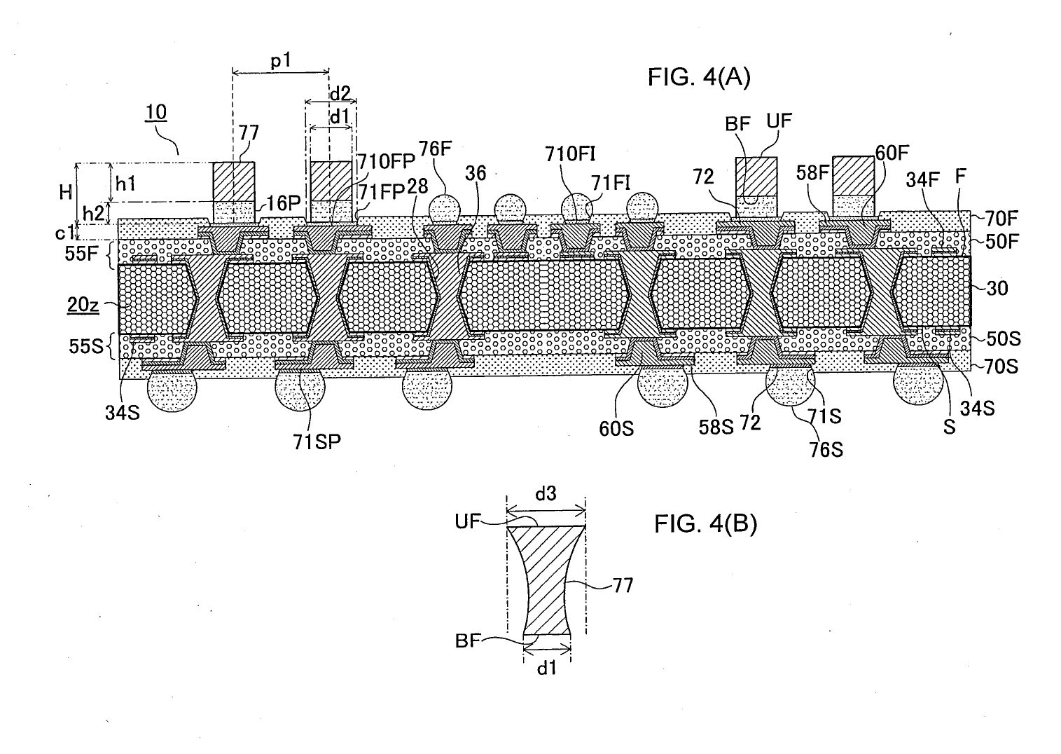

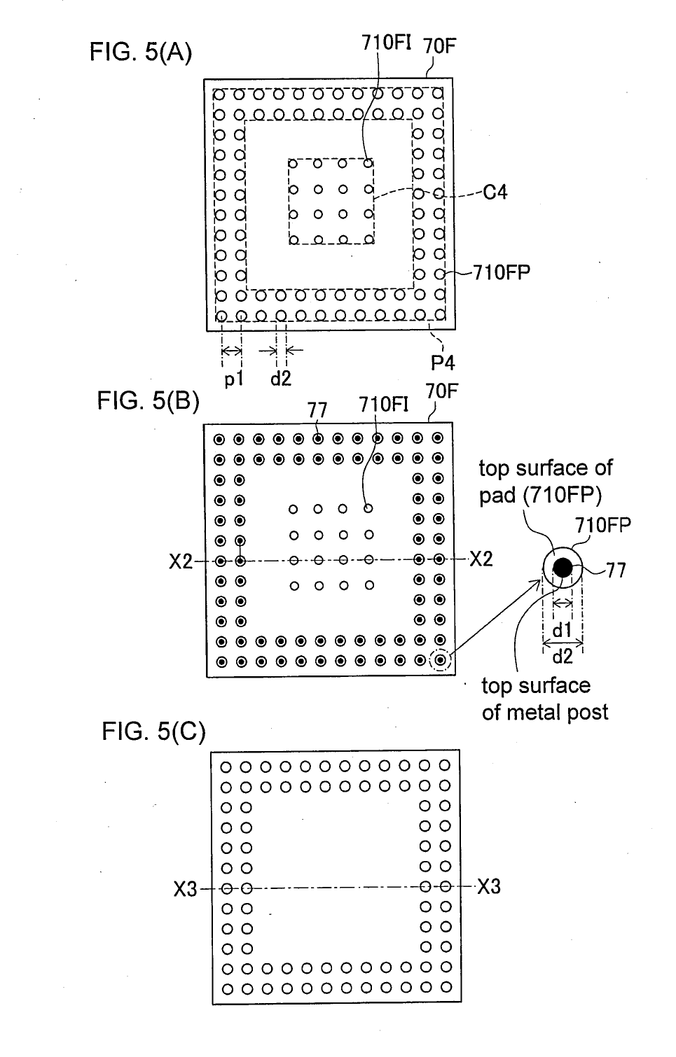

Printed wiring board 10 includes pads (first pads) (710FI) for mounting electronic component 90 such as an IC chip, and pads (second pads) (710FP) for mounting another printed wiring board (upper substrate) 110. Electronic component 900 such as a memory is mounted on the other printed wiring board. Pad group (C4) is formed with multiple pads (710FI) (see FIG. 5(A)), and is positioned in substantially the center of printed wiring board 10. Pads (710FP) are formed in circumferential region (P4) surrounding pad group (C4) (see FIG. 5(A)). Then, bonding posts (metal posts) 77 are formed on pads (710FP) for mounting an upper substrate. The shape of metal posts is a circular column or a rectangular column, for example. Metal posts 77 work to electrically connect printed wiring board 10 and printed wiring board 110. In addition, even if pitch (p1) of pads (710FP) is 0.3 mm or less, the distance between printed wiring board 10 of the present embodiment and printed wiring board (upper substrate) 110 is ensured by metal posts 77. Even if pitch (p1) of pads (710FP) is 0.25 mm or less, the distance between printed wiring board 10 of the present embodiment and printed wiring board (upper substrate) 110 is made constant by metal posts 77. Insulation between adjacent pads is made certain. Pitch (p1) is the distance between the centers of adjacent pads (710FP), or the distance between the gravity centers of adjacent pads (710FP) (see FIG. 4(A) and FIG. 5(A)).

It is an option for the printed wiring board of the embodiment to be a printed wiring board with a core substrate or to be a coreless wiring board. A printed wiring board with a core substrate and its manufacturing method are shown in JP2007-227512A, for example. The entire contents of this publication are incorporated herein by reference. A coreless wiring board and its manufacturing method are shown in JP2005-236244A, for example. The entire contents of this publication are incorporated herein by reference. A coreless wiring board has alternately laminated interlayer resin insulation layers and conductive layers, and the thickness of each interlayer resin insulation layer is 60 μm or less, for example. Printed wiring board 10 of the first embodiment has core substrate 30. The core substrate includes insulative substrate (20z) having first surface (F) and second surface (S) opposite the first surface, first conductive layer (34F) formed on first surface (F) of the insulative substrate and second conductive layer (34S) formed on the second surface of the insulative substrate. The core substrate further includes through-hole conductor 36 formed by filling plated film in penetrating hole 28 for a through-hole conductor in insulative substrate (20z). Through-hole conductor 36 connects first conductive layer (34F) and second conductive layer (34S). The first surface of the core substrate corresponds to the first surface of the insulative substrate, and the second surface of the core substrate corresponds to the second surface of the insulative substrate.

Interlayer resin insulation layer (50F) (uppermost interlayer resin insulation layer) is formed on first surface (F) of core substrate 30. Conductive layer (58F) (uppermost conductive layer) is formed on interlayer resin insulation layer (50F). Conductive layer (58F) is connected to first conductive layer (34F) and through-hole conductors by via conductors (60F) (uppermost via conductors) penetrating through interlayer resin insulation layer (50F). Upper buildup layer (55F) is formed with interlayer resin insulation layer (50F), conductive layer (58F) and via conductors (60F). In the first embodiment, the upper buildup layer is single-layered. The uppermost conductive layer has pads (710FI, 710FP). Pads (710FI, 710FP) correspond to the top surface of a conductive circuit or of an uppermost via conductor included in the uppermost conductive layer.

Interlayer resin insulation layer (50S) (lowermost interlayer resin insulation layer) is formed on second surface (S) of core substrate 30. Conductive layer (58S) (lowermost conductive layer) is formed on interlayer resin insulation layer (50S). Conductive layer (58S) is connected to second conductive layer (34S) and through-hole conductors by via conductors (60S) (lowermost via conductors) penetrating through interlayer resin insulation layer (50S). Lower buildup layer (55S) is formed with interlayer resin insulation layer (50S), conductive layer (58S) and via conductors (60S). In the first embodiment, the lower buildup layer is single-layered. The lowermost conductive layer has BGA pad (71SP) for connection with a motherboard. Pad (71SP) corresponds to the top surface of a conductive circuit or of a lowermost via conductor included in the lowermost conductive layer.

Upper solder-resist layer (70F) is formed on the upper buildup layer, and lower solder-resist layer (70S) is formed on the lower buildup layer. Solder-resist layer (70F) has opening (first opening) (71FI) to expose pad (710FI) and opening (second opening) (71FP) to expose pad (710FP). Solder-resist layer (70S) has opening (71S) to expose BGA pad (71SP). On pad (710FI) and BGA pad (71SP), bonding materials (76F, 76S) such as solder bumps or Sn film are formed for connection with an electronic component or a motherboard. It is an option not to form such bonding material.

FIG. 4 is a cross-sectional view of printed wiring board 10 having bonding materials (76F, 76S) according to the present embodiment. FIG. 5(A) shows a mounting surface of the printed wiring board of the embodiment. The mounting surface includes upper solder-resist layer (70F) and pads (710FI, 710FP). A metal post is bonded to pad (710FP). Top surfaces of metal posts 77, solder-resist layer (70F) and pads (710FI, 710FP) are shown in FIG. 5(B).

Metal post 77 has top surface (UF) and bottom surface (BF) opposite the top surface. In addition, metal post 77 has a side surface between the top surface and bottom surface. The bottom surface of a metal post faces pad (710FP). FIG. 4 shows a cross-sectional view of printed wiring board 10 taken at (X2-X2) in FIG. 5(B). Metal post 77 is formed on pad (710FP) through bonding material (16P) such as solder or Sn film disposed in between. Pad (710FP) and metal post 77 are bonded by bonding material (16P). Metal post 77 is adhered to pad (710FP) by the bonding material. The shape of a metal post shown in FIG. 4 and FIG. 5(B) is a circular column. Diameter (d2) of pad (710FP) is 55 μm˜210 μm. The diameter of a pad indicates the diameter of the conductor (conductive circuit or via conductor) exposed from the solder-resist layer. Diameter (d1) of metal post 77 (diameter of the bottom surface of a metal post) is smaller than diameter (d2), and is 50 μm˜200 μm. Regarding diameter (d1) of a metal post and diameter (d2) of a pad, the ratio (d1/d2) is preferred to be 0.5 to 0.9. By so setting, the pitch among pads is reduced. Even if pitch (p1) is 0.3 mm or less, connection reliability is high between printed wiring board 10 and the upper substrate. Also, insulation reliability is high between metal posts. Distance (pitch) (p1) between adjacent pads (710FP) is 100 μm˜300 μm. If pitch (p1) is smaller than 100 μm, the insulation reliability between metal posts tends to decrease. Also, since metal posts become thinner, connection reliability is lowered between the upper substrate and printed wiring board 10. If pitch (p1) exceeds 300 μm, the size of printed wiring board 10 increases. Accordingly, stress exerted on the metal posts increases, and connection reliability is lowered between the upper substrate and printed wiring board 10.

When pitch (p1) is set at 0.3 mm or less, the height (h1) (distance from the top surface to the bottom surface) of metal post 77 is 75 μm˜200 μm, diameter (d1) of the metal post is 75 μm˜200 μm, and thickness (h2) of bonding material (16P) such as a solder layer is 10 μm˜30 μm. Connection reliability between a printed wiring board of the embodiment and the upper substrate, as well as insulation reliability between metal posts, is enhanced.

When pitch (p1) is set at 0.25 mm or less, height (h1) of metal post 77 is 100 μm˜200 μm, diameter (d1) of the metal post is 50 μm˜200 μm, and thickness (h2) of bonding material (16P) such as a solder layer is 10 μm˜20 μm. Connection reliability between a printed wiring board of the embodiment and an upper substrate, as well as insulation reliability between metal posts, is enhanced.

The aspect ratio of a metal post (height (h1)/diameter (d1)) is preferred to be greater than 1. The stress between an upper substrate and a printed wiring board of the embodiment is mitigated by the metal post. Connection reliability is enhanced. The aspect ratio (h1/d1) is preferred to be 1.5˜3. The stress between an upper substrate and printed wiring board 10 is mitigated. In addition, the metal post does not suffer deterioration from fatigue. Connection reliability between the upper substrate and printed wiring board 10 is enhanced.

If thickness (h2) of bonding material (16P) is smaller than a predetermined value, metal post 77 is removed from pad (710FP). If thickness (h2) of bonding material (16P) is greater than a predetermined value, such bonding material is likely to cause short circuiting between metal posts.

The side surface of a metal post is preferred to be curved so that the diameter of the metal post between the top surface and the bottom surface is narrowed. An example is shown in FIG. 4(B). Top-surface diameter (d3) of a metal post is preferred to be greater than bottom-surface diameter (d1). Connection reliability between the upper substrate and the metal post is improved, and their alignment is easier. Since a metal post has a narrowed portion, the metal post tends to deform and the stress is thereby mitigated. If pitch (p1) between pads (710FP) is 0.3 mm or less, connection reliability will not decrease between a printed wiring board of the embodiment and an upper substrate.

When a metal post and a printed wiring board of the embodiment, or a metal post and an upper substrate, are connected by solder, it is preferred that no metal film made of a noble metal such as gold be formed on the side surface of the metal post. Since noble metals are hard to oxidize, if a metal film is formed on the side surface of a metal post, solder is wet-spread on the side surface of the metal post. Thus, the insulation distance between adjacent metal posts is reduced. Insulation reliability decreases between metal posts.

Regarding distance (H) from the top surface of pad (710FP) and the top surface of a metal post and thickness (c1) of pad (710FP), the ratio (H/c1) is preferred to be 5 or greater but 30 or smaller. When protective film 72 is formed on the conductor exposed from an opening of a solder-resist layer, the pad includes protective film 72. Thus, in FIG. 4, thickness (c1) of a pad is the distance from the top surface of interlayer resin insulation layer (50F) to the top surface of protective film 72. Protective film 72 is for preventing oxidation of a pad. Examples of protective films are Ni/Au, Ni/Pd/Au, Sn, OSP and the like.

When pitch (p1) is 0.3 mm or less, the ratio (H/c1) is preferred to be 7 or greater but 25 or smaller.

Since pad (710FP) is the base of a metal post, if the ratio (H/c1) is too great, the metal post is removed from the pad, or the reliability of the metal post decreases. If the ratio (H/c1) is too small, it is difficult for the metal post to mitigate stress. Connection reliability is lowered.

A metal post is manufactured when metal wire having a predetermined diameter is cut into a predetermined length. Alternatively, a metal post is formed by blanking a metal foil. By selecting the thickness of a metal foil and a die to be used, a desired metal post is obtained. For example, a bonding material is formed on a pad, and a metal post is mounted using a mounter or the like on the bonding material. Then, the metal post is bonded to the pad by the bonding material through a reflow process. It is an option to form solder on the surface of a metal post by plating or by sputtering. Another option is to form a metal film such as gold or tin on the surface of a metal post. Solder may be formed on a metal post with a metal film disposed in between. When a metal post is covered by solder, stress is mitigated by the solder formed on the metal post. Reliability of the metal post is enhanced. A metal post covered by solder is preferred to be used in a printed wiring board according to a later-described third embodiment. Short circuiting between metal posts is prevented by a resin layer. The surface of a metal post includes the top surface, bottom surface and side surface of the metal post. It is yet another option to form solder or metal film only on the bottom surface of a metal post. For example, a metal post is embedded in resin such as plating resist, and the bottom surface of the metal post will be exposed by polishing or the like. Then, solder or metal film is formed on the bottom surface of the metal post. Accordingly, a metal post with attached bonding material is formed. When a metal post with attached bonding material is used, the metal post with attached bonding material may be directly bonded to pad (710FP) by a reflow or ultrasonic process. Alternatively, through a bonding material such as solder or Sn formed on a pad, a metal post with attached bonding material may be bonded to the pad by a reflow or ultrasonic process.

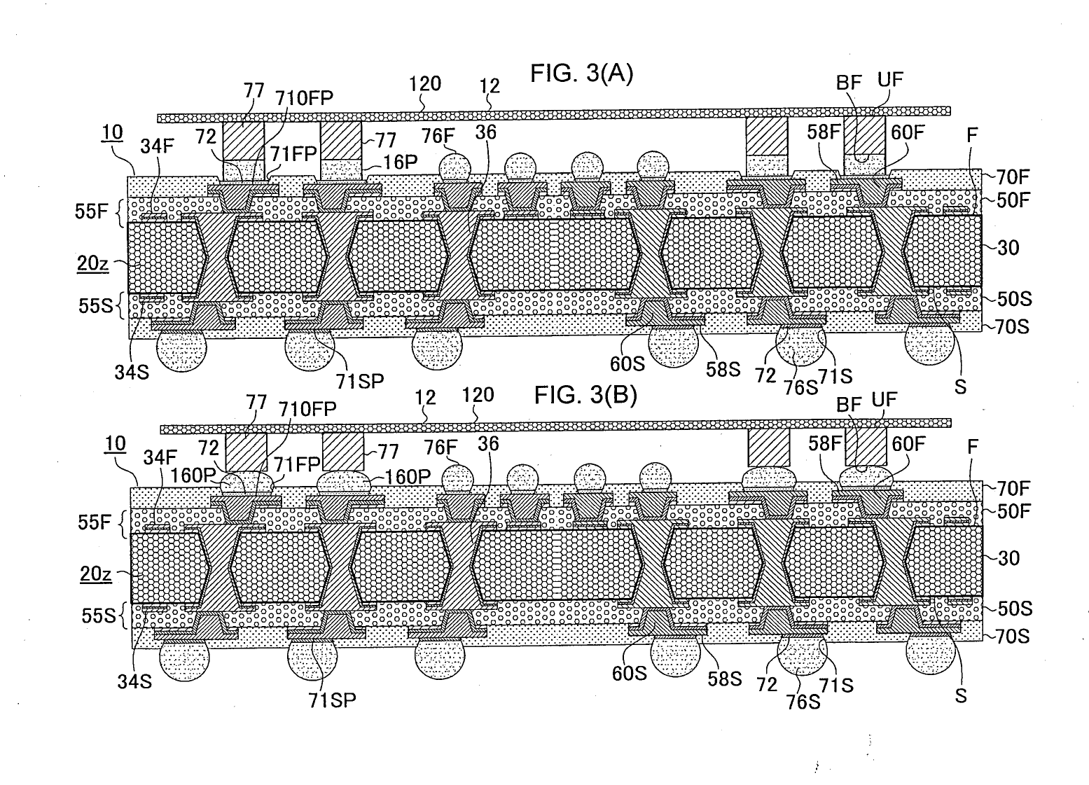

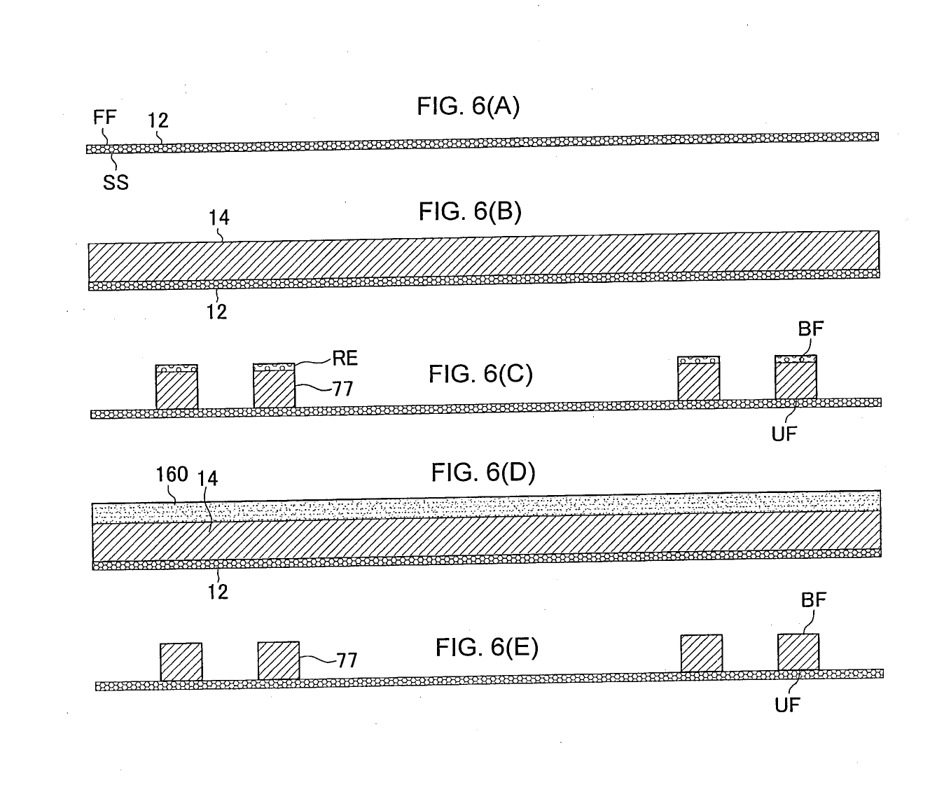

Alternatively, a metal post may also be formed by etching a metal foil. Support film 12 having first surface (FF) and second surface (SS) opposite the first surface is prepared (FIG. 6(A)). An adhesive layer is formed on the first surface of the support film. The adhesive layer is omitted from the drawings. Metal foil 14 such as copper foil is adhered to the first surface of the support film (FIG. 6(B)). Then, etching resist (RE) is formed on the metal foil, and the metal foil exposed from the etching resist is removed (FIG. 6(C)). Further, the etching resist is removed (FIG. 6(E)). Accordingly, metal post 77 with top surface (UF) and bottom surface (BF) opposite top surface (UF) is formed on the support film. The top surface of a metal post is adhered to the support film. Etching resist (RE) is formed based on the position of pad (710FP). Thus, the position of a metal post on the support film corresponds to the position of pad (710FP). A metal post on the support film is mounted on pad (710FP) on the printed wiring board through bonding material (160P) (FIG. 3(B)). In such a case, bonding material (160P) such as a solder bump is formed in advance on pad (710FP). A metal post is bonded to the pad by the bonding material by a reflow or ultrasonic process. The adhesiveness of the adhesive layer of the support film is weaker than the adhesiveness of the bonding material, thus enabling the support film to be removed from the top surface of the metal post. A metal post is formed on pad (710FP) (FIG. 4(A)).

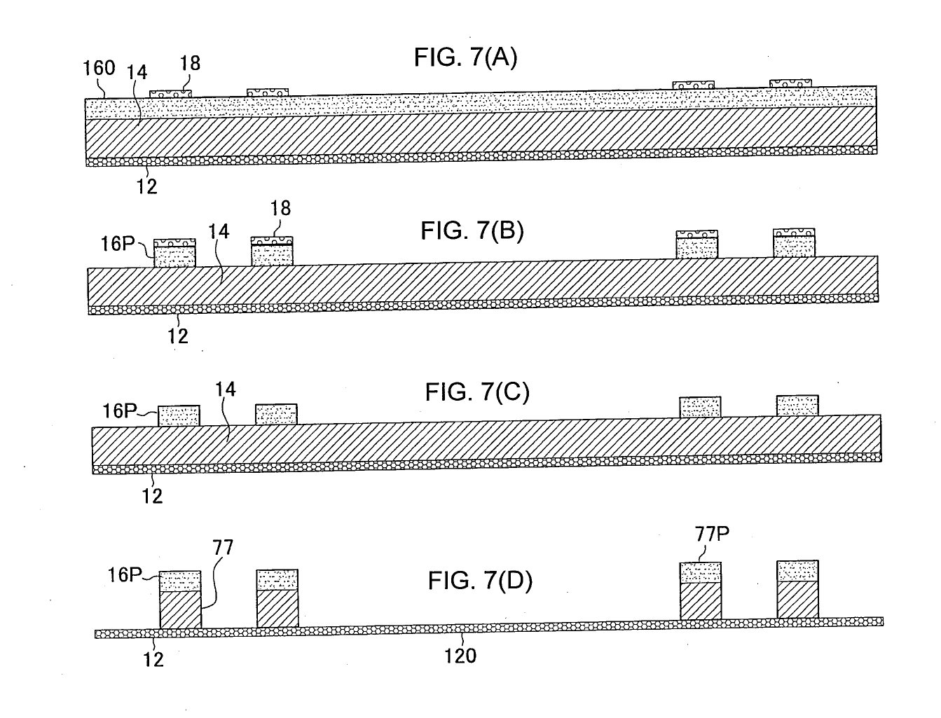

On metal foil 14 on the support film (FIG. 6(B)), bonding layer 160 such as solder or Sn may be formed (FIG. 6(D)). Then, etching resist 18 is formed on bonding layer 160 (FIG. 7(A)). Next, bonding layer 160 is etched away (FIG. 7(B)). Furthermore, using the same etching resist, the metal foil is etched away (FIG. 7(D)). The etching solution for etching bonding layer 160 is preferred to be different from the etching solution for etching the metal foil. The bonding layer is selectively removed, and then the metal foil is selectively removed. Alternatively, the bonding layer may be removed first, followed by the removal of the etching resist (FIG. 7(C)). Bonding material (16P) is formed from the bonding layer. After that, the metal foil is etched using bonding material (16P) as the etching mask. Metal post (77P) with attached bonding material is manufactured (FIG. 7(D)). When a metal post with attached bonding material is used, the metal post with attached bonding material may be bonded directly on a pad by a reflow or ultrasonic process. Alternatively, through bonding material (160P) on a pad, a metal post with attached bonding material may be bonded to the pad by a reflow or ultrasonic process. By the method above, a metal post is manufactured separately from a printed wiring board. A metal post is not formed on a printed wiring board.

Metal wire or metal foil is preferred to be made of copper or copper alloy. A metal post is preferred to be made of copper or copper alloy. Bonding material is preferred to be Sn/Ag solder or Sn/Ag/Cu solder.

On pads (710FP), a printed wiring board according to the first embodiment has metal posts 77 manufactured separately from the printed wiring board. Metal posts 77 are bonded to pads (710FP) by bonding material (16P).

In the embodiment, metal posts are manufactured separately from printed wiring board 10. For example, metal posts are formed from a metal foil or metal wire. Variations in the height of metal posts in the embodiment are smaller than when metal posts are formed directly on a printed wiring board by plating. Accordingly, production yield is high when an upper substrate is mounted on printed wiring board 10 through such metal posts. Printed wiring board 10 is manufactured to provide ease of mounting. When the heights of metal posts vary, stress tends to concentrate on a certain metal post, and connection reliability is thereby lowered. However, according to the embodiment, since variations in the height of metal posts are small, connection reliability between the upper substrate and printed wiring board 10 is high.

Diameter (d1) of a metal post manufactured separately from the printed wiring board is smaller than diameter (d2) of a pad. Thus, even if pitch (p1) is small, the distance in the space between adjacent metal posts is set greater. In the embodiment, pitch (p1) is set smaller. Since the distance in the space between adjacent metal posts is greater, even if pitch (p1) is 0.3 mm or less, insulation reliability between metal posts is high. When pitch (p1) is 0.25 mm or less, metal posts become thinner. To enhance connection reliability, the aspect ratio (h1/d1) of a metal post is preferred to be 1.5 or greater. When the number of pads (710FP) increases, the size of a printed wiring board increases. However, if the aspect ratio (h1/d1) of a metal post is 2 or greater, stress, caused by the difference between the physical properties of an upper substrate and the physical properties of a printed wiring board, is mitigated by metal posts. If the ratio (h1/d1) exceeds 3.5, the metal post suffers deterioration from heat cycles. Examples of physical properties are a thermal expansion coefficient and Young's modulus.

As shown in FIG. 1, printed wiring board 10 and upper substrate 110 are connected by a highly rigid metal post 77 and bonding materials (16P, 112) sandwiching metal post 77. Bonding materials are preferred to be solder. The rigidity of bonding materials is lower than the rigidity of a metal post. Thermal stress between an upper substrate and the printed wiring board is mitigated by the bonding materials. The strength of an electronic device having an upper substrate and a printed wiring board is maintained by metal posts. Warping caused by the difference between the physical properties of an upper substrate and the physical properties of a printed wiring board will be reduced in the electronic device.

In the embodiment, metal posts are formed from metal foil or metal wire. Then, metal posts are mounted on pads by a reflow or ultrasonic process. Thus, the manufacturing method is simplified.

FIGS. 6 and 7 show a method for manufacturing a metal post by etching.

(1) Support film 12 is prepared (FIG. 6(A)). Support film is formed with a base film having first surface (FF) and second surface (SS) opposite the first surface and with an adhesive layer formed on the first surface of the base film. An example of the support film is Ultra High Temperature Adhesive Transfer Tape 9079 made by Sumitomo 3M Limited.

(2) Metal layer 14 such as 0.1 mm-thick metal foil (copper foil) is laminated on the adhesive layer of support film 12 (FIG. 6(B)). The thickness of a metal layer is selected according to the height of metal post 77. The metal layer is preferred to be copper foil or copper-alloy foil. Copper foil is used in the embodiment.

(3) On copper foil 14, 20 μm-thick bonding layer 160 is formed by electrolytic solder plating (FIG. 6(D)). The bonding layer is formed by solder plating, but it is also an option to form a bonding layer by applying solder paste.

(4) Etching resist 18 is formed on bonding layer 160 (FIG. 7(A)). Positions where etching resist 18 is formed correspond to the positions of pads (710FP) shown in FIG. 5(A). Etching resist 18 is arranged the same as pads (710FP) are arrayed. The shape of each etching resist 18 is a circular column.

(5) Bonding layer 160 exposed from etching resist 18 is removed by selective etching (FIG. 7(B)). An example of the etching solution is E-Process-WL made by Meltex Inc. Etching resist 18 is removed (FIG. 7(C)). The metal foil is selectively removed using bonding material (16P) as the etching mask (FIG. 7(D)). An example of the etching solution is SF-5420 made by Mec Co., Ltd. Metal post 77 shaped in a substantially circular column is formed on the support film. In addition, bonding material (16P) made of solder or the like and shaped in a substantially circular column is formed on metal post 77. Metal post 77 with attached bonding material is formed (FIG. 7(D)). FIG. 5(C) is a plan view showing metal posts on a support film and the support film exposed through metal posts. FIG. 7(D) is a cross-sectional view taken at (X3-X3) in FIG. 5(C). It is an option not to form a bonding material on a metal post. Since a metal post is formed by removing the metal foil exposed from the etching resist and etching mask, the metal foil has a narrowed portion between the top and bottom surfaces (FIG. 4(B)). The side surface of a metal post is curved. The surface facing the support film is the top surface of a metal post. A metal post is formed by etching the bottom-surface side of the metal post. By decreasing the etching speed, top-surface diameter (d3) of a metal post is made greater than the bottom-surface diameter (d1). A bonding material such as solder is formed on the bottom surface of a metal post. Bottom surface (BF) of a metal post faces pad (710FP).

The following is another example.

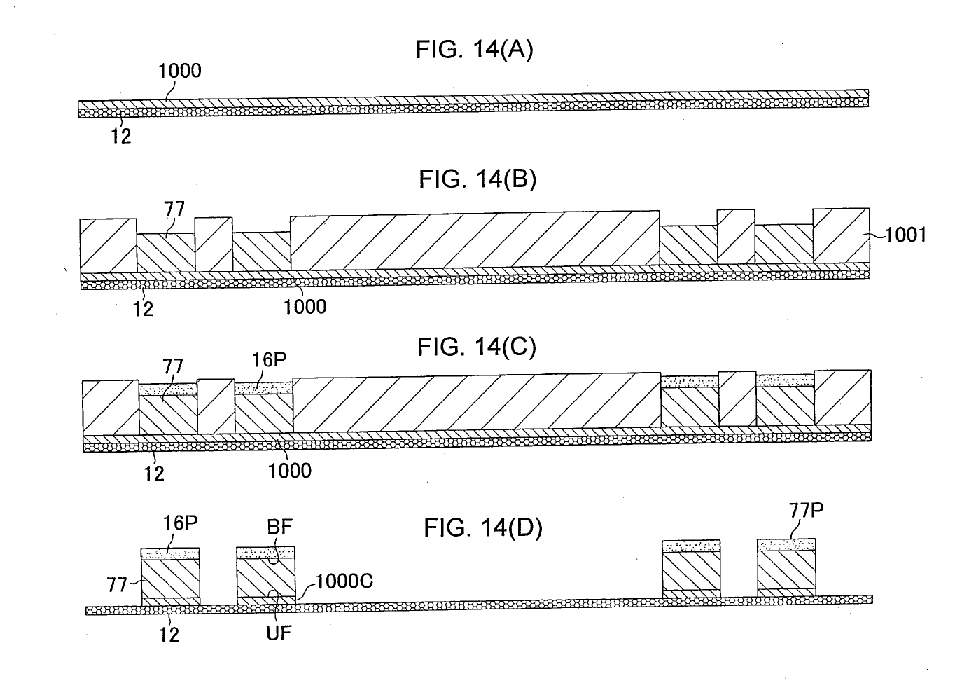

Seed layer 1000 is formed by sputtering on the adhesive layer of support film 12 (FIG. 14(A)). The seed layer is made of copper or the like. The thickness of the seed layer is 0.1 μm˜3 μm, and plating resist 1001 is formed on the seed layer. Metal post 77 is formed on the seed layer exposed from the plating resist (FIG. 14(B)). The seed layer is a copper-plated film.

A printed wiring board is manufactured by numerous steps. If a metal post is directly formed on a printed wiring board by performing plating, the thickness of the seed layer varies. Also, the degree of warping is greater on the surface where plating is formed, increasing variations in the height of metal posts. By contrast, since metal posts of the embodiment are formed on a support film as a starting material, variations in the height of metal posts are small. When variations in the height of metal posts are greater, the variations may be reduced by polishing the bottom surfaces of the metal posts.

The height of a metal post is approximately 100 μm. Bonding material (16P) is formed on a metal post (FIG. 14(C)). The thickness of the bonding material is 10 μm. Plating resist 1001 is removed. Seed layer 1000 exposed from metal posts is removed (FIG. 14(D)). Metal post 77P with attached bonding material is formed. It is an option not to form a bonding material such as solder or Sn on a metal post.

According to such a method, since a metal post is formed in an opening of the plating resist, the side surface of a metal post is substantially straight. For example, a metal post is shaped in a circular column. Bonding material layer (16P) such as solder or Sn is formed on the bottom surface of a metal post. In FIG. 14(D), conductive layer (1000C) made of the seed layer is formed on the top surface of metal post 77. Since a metal post is made of rigid copper alloy and a connecting point with the upper substrate is formed of conductive layer (1000C) made of soft copper or the like, connection reliability is enhanced.

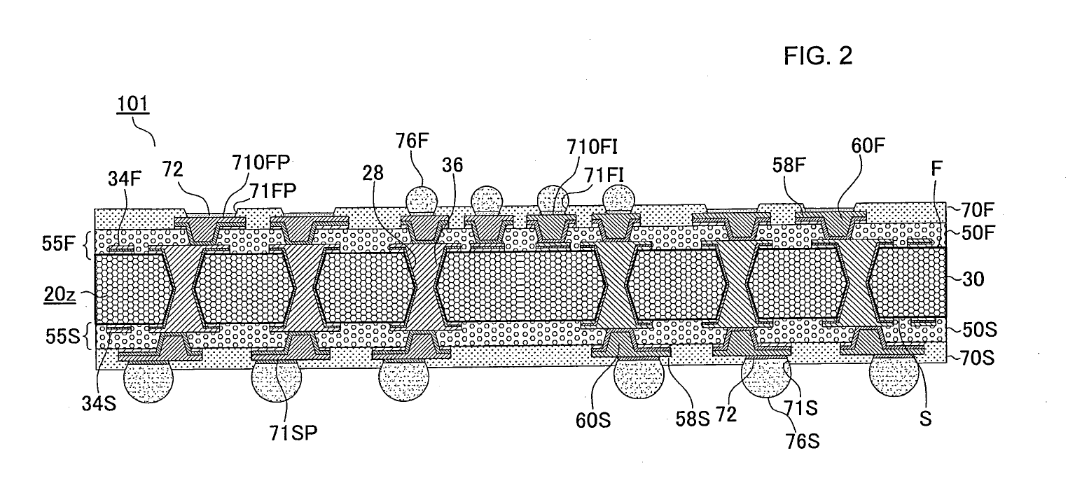

A method for bonding metal post 77 to a printed wiring board is shown in FIG. 2˜5.

Intermediate printed wiring board 101 is shown in FIG. 2. The intermediate printed wiring board shown in FIG. 2 has pad (710FP), and a metal post is mounted on pad (710FP). The intermediate printed wiring board shown in FIG. 2 is manufactured by, for example, a method described in JP2012-069926A. The entire contents of this publication are incorporated herein by reference. OSP (organic solderability preservative) film 72 is formed on pad (710FP) exposed in opening (71FP) of solder-resist layer (70F) of the printed wiring board. Instead of OSP film, other protective film such as nickel-gold film or nickel-palladium-gold film may also be formed.

As shown in FIG. 3, pad (710FP) and metal post are aligned, and support film 120 with attached metal posts shown in FIG. 7(D) is placed on the intermediate printed wiring board. At that time, the bottom surface of a metal post faces pad (710FP). Bonding material (16P) is placed on pad (710FP). Both the support film with attached metal posts and the intermediate wiring board have alignment marks. They are aligned using their respective alignment marks.

When support film 120 with attached metal posts are mounted on intermediate printed wiring board 101 shown in FIG. 2, heat is applied on bonding material (16P) on the bottom surface of metal post 77 (FIG. 3(A)). The bonding material such as solder is melted, and metal post 77 is thereby bonded to pad (710FP) by the bonding material. The adhesiveness of a metal post and the adhesive layer of the support film is weaker than the adhesiveness of a metal post and the bonding material, or than the adhesiveness of pad (710FP) and the bonding material. Thus, the support film is removed from the metal post. Printed wiring board 10 is completed (FIG. 4).

Electrode 92 of IC chip 90 is connected to pad (760FI) of the printed wiring board through solder bump (76F). IC chip 90 is mounted on printed wiring board 10. Then, another printed wiring board 110 is bonded to metal post 77 through solder bump 112. Other wiring board 110 is mounted on printed wiring board 10 (FIG. 1).

In the method for manufacturing a printed wiring board according to the first embodiment, metal posts 77 are formed by etching metal foil (copper foil) 14 with a uniform thickness. When metal posts are formed by cutting metal wire, the same effects are exhibited in printed wiring board 10. Thus, the height of each metal post is substantially the same. The manufacturing method according to the first embodiment is capable of manufacturing metal posts with high reliability, and metal posts are thereby positioned at a fine pitch.

### Second Embodiment

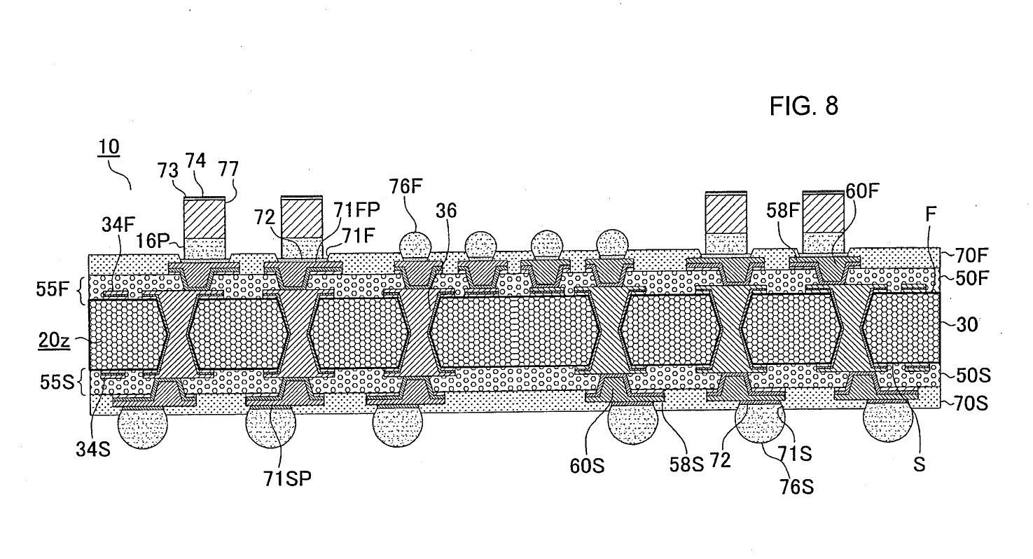

FIG. 8 shows printed wiring board 10 according to a second embodiment.

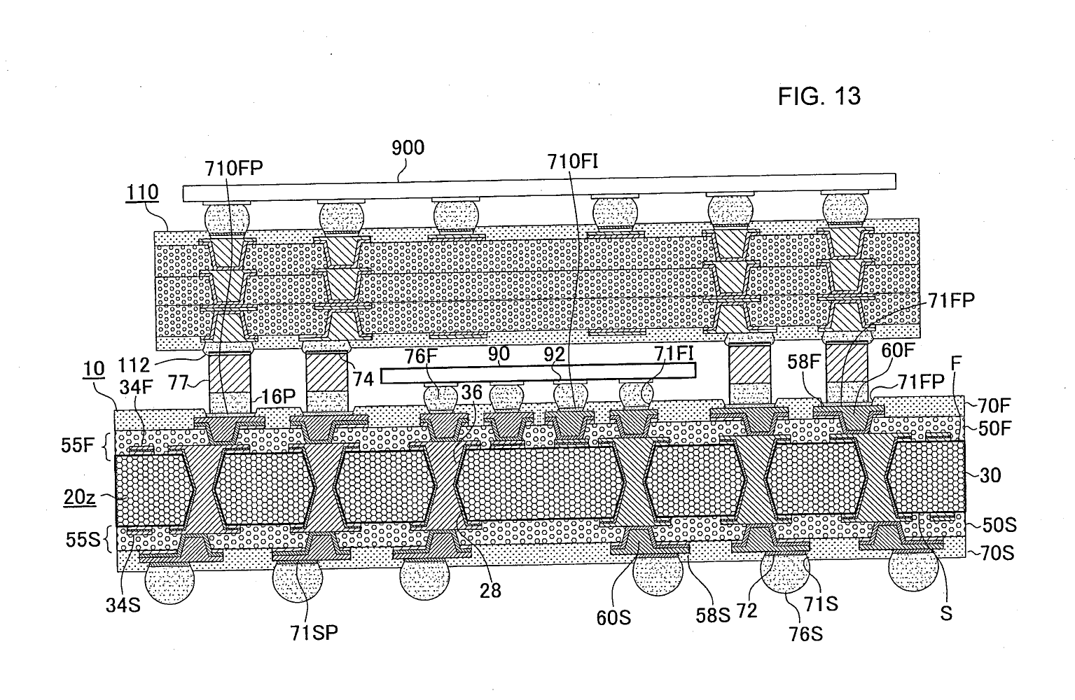

In a printed wiring board of the second embodiment, a metal film made up of nickel film 73 and gold film 74 on the nickel film is formed on the top surface of metal post 77. Here, the metal film may also be formed by nickel-palladium-gold. FIG. 13 shows an application example of a printed wiring board according to the second embodiment. An electronic component such as IC chip 90 is mounted on a printed wiring board of the second embodiment. Another printed wiring board (upper substrate) 110 the same as in the first embodiment is mounted on the printed wiring board of the second embodiment. In the second embodiment, the outermost layer of the metal film formed on the top surface of metal post 77 is made of gold film 74. In each embodiment, a metal post is made of copper or copper alloy. The solderability to gold is higher than the solderability to copper or copper alloy. Thus, bonding material 112 such as solder for the upper substrate is hard to wet-spread on the side surface of a metal post. Accordingly, the thickness of bonding material 112 for the upper substrate is likely to become uniform. Also, strong bonding of a metal post and the bonding material for the upper substrate is achieved. It is easier to keep the distance uniform between printed wiring board 10 and other printed wiring board 110. Connection reliability is enhanced between printed wiring board 10 and other printed wiring board 110.

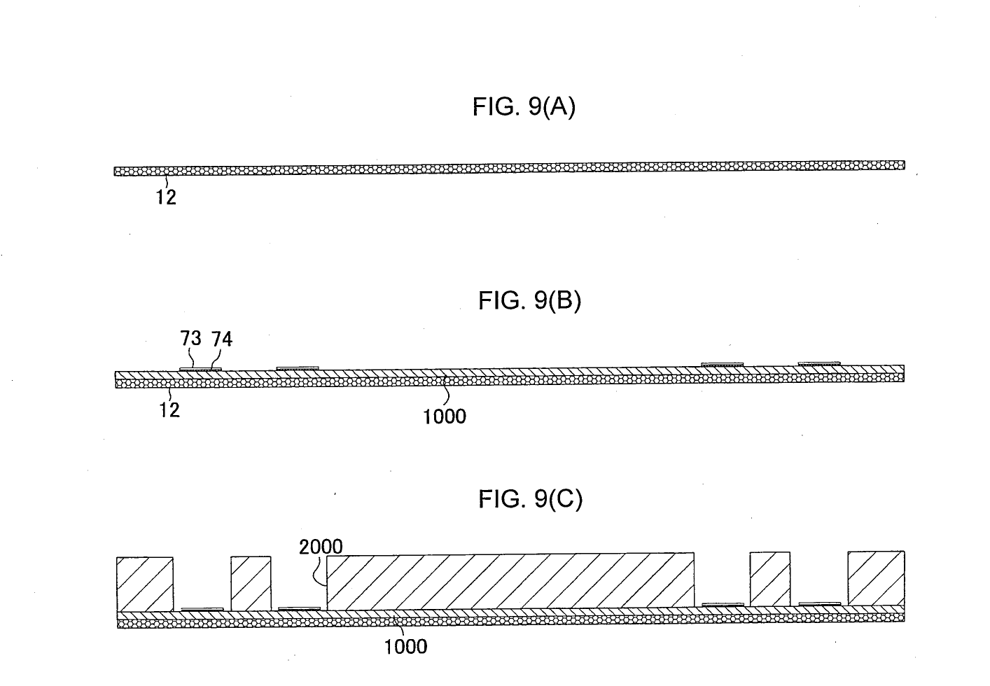

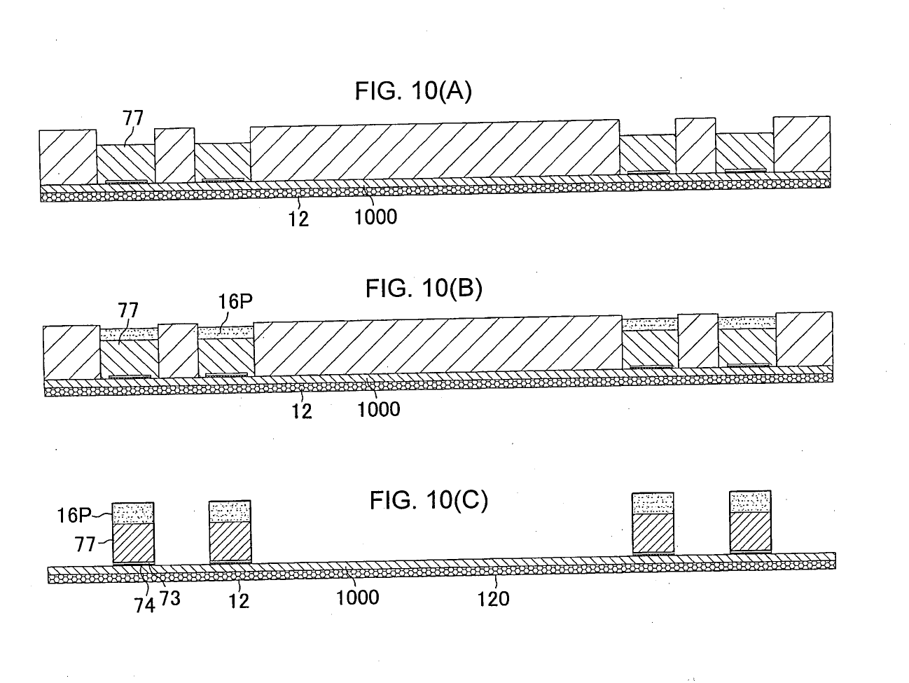

FIGS. 9 and 10 show a method for manufacturing a metal post for a printed wiring board according to the second embodiment.

(1) Support film 12 is prepared (FIG. 9(A)).

(2) Seed layer 1000 made by sputtering copper or the like is formed on the support film (FIG. 14(A)). The thickness of the seed layer is approximately 0.1 μm.

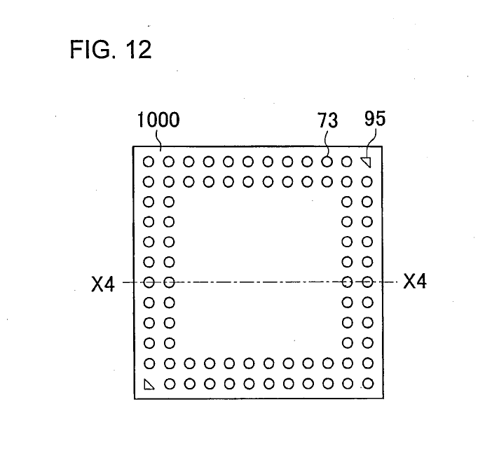

(3) On the seed layer formed on support film 12, gold layer 74 and nickel layer 73 are formed in that order using a lift-off method (FIG. 9(B)). A metal film made of nickel and gold is formed on the support film. A palladium layer may also be formed between the gold layer and the nickel layer. FIG. 12 is a plan view showing the metal film on support film 12 and the seed layer exposed through the metal film, and FIG. 9(B) is a cross sectional view taken at (X4-X4) in FIG. 12(A). The array of metal film is the same as the array of pads (710FP). At that time, alignment mark 95 is formed by the metal film.

(4) Plating resist is formed on the seed layer and metal film. At that time, alignment mark 95 is not covered by plating resist. Plating resist is formed based on alignment mark 95 (FIG. 9(C)). Metal film is exposed through opening 2000 of the plating resist. The size of an opening of the plating resist is greater than the size of the metal film. The thickness of the plating resist is approximately 120 μm. Metal post 77 is formed on the metal film by electrolytic copper plating (FIG. 10(A)). The thickness of a metal post is approximately 100 μm. Bonding material (16P) is formed on a metal post by electrolytic solder plating (FIG. 10(B)). The thickness of bonding material (16P) is approximately 20 μm.

(5) Plating resist 18 is removed. The seed layer, metal film, metal post 77 and bonding material (16P) are formed in that order on the support film (FIG. 10(C)).

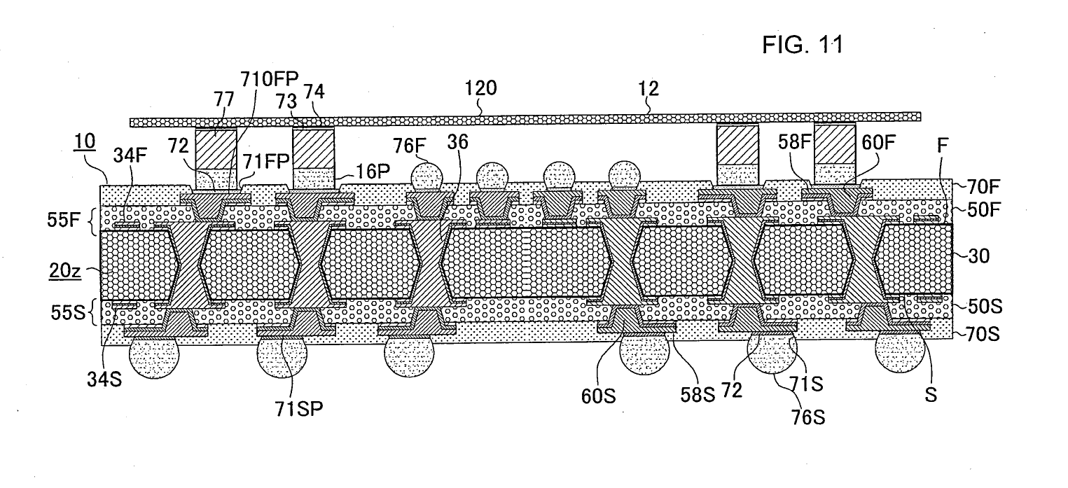

FIG. 11 shows a method for bonding metal post 77 to the printed wiring board.

Support film 120 with attached metal posts shown in FIG. 10(C) is placed on a printed wiring board. At that time, the position of metal post 77 is aligned with the position of pad (710FP).

Heat is applied to bonding material (16P) such as solder. The metal post is bonded to pad (710FP) through bonding material (16P). The support film is removed. Seed layer 1000 is removed by etching. The metal film formed on the top surface of the metal post is exposed. Printed wiring board 10 is completed (FIG. 8).

Electrode 92 of IC chip 90 is connected to a pad of the printed wiring board through solder bump (76F) so that IC chip 90 is mounted on printed wiring board 10. Then, the other printed wiring board 110 is bonded to metal post 77 through solder bump 112 to mount that printed wiring board on printed wiring board 10 (FIG. 13).

### Third Embodiment

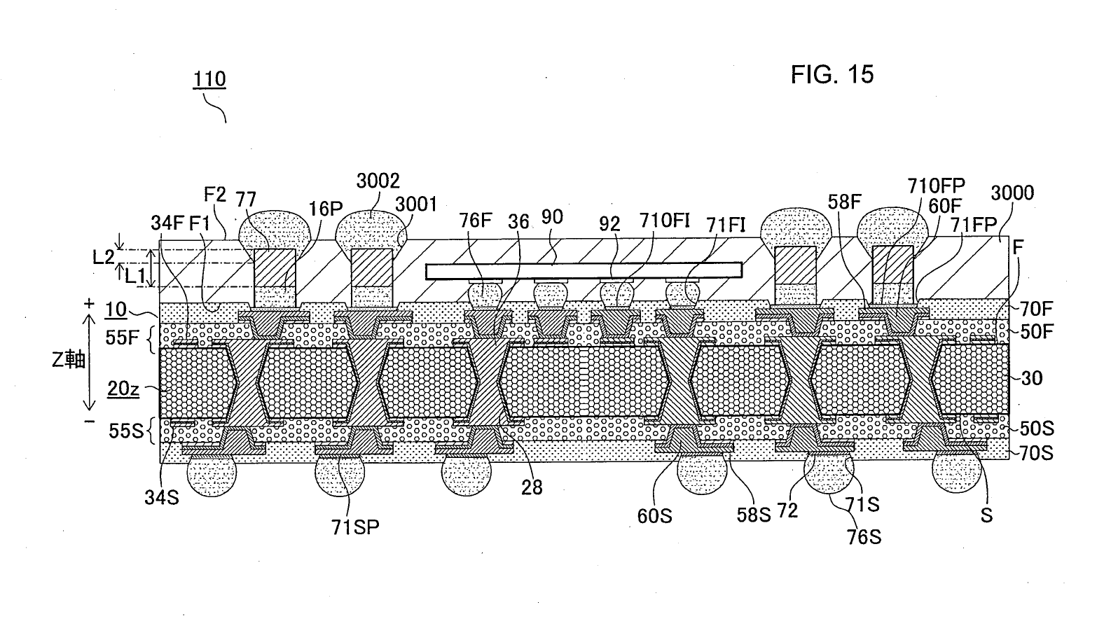

FIG. 15 shows a printed wiring board according to a third embodiment. Axis Z is shown in FIG. 15, where the upper portion is in direction (+Z), and the lower portion is in direction (−Z).

In the printed wiring board of the third embodiment, resin layer 3000 is formed on the mounting surface of the printed wiring board according to the first embodiment. The resin layer has first surface (F1) and second surface (F2) opposite the first surface, and the first surface of the resin layer faces the mounting surface. As shown in FIG. 15, the resin layer is also formed in the space between metal posts. The second surface of the resin layer is preferred to be positioned above the top surface of a metal post. The thickness of resin layer 3000 is greater than the height of a metal post. Insulation reliability between metal posts is enhanced by the resin layer.

As shown in FIG. 15, the resin layer has an opening 3001 to expose the top surface of a metal post (opening to expose a metal post). Then, material 3002 is formed in the opening to bond the upper substrate and printed wiring board 10 (bonding material for the upper substrate). Material 3002 formed in an opening for bonding the upper substrate and printed wiring board 10 (bonding material for the upper substrate) is solder or conductive paste. To enhance connection reliability between the bonding material for the upper substrate and a metal post, opening 3001 to expose a metal post is preferred to expose the side surface of the metal post as well. The bonding material for the upper substrate is formed on the top surface and side surface of a metal post. Regarding length (L2) of the side surface exposed in the opening to expose a metal post, and height (L1) of the metal post, the ratio (L2/L1) is preferred to be 0.1-0.7. If the ratio (L2/L1) is smaller than 0.1, since bonding strength is weak between the metal post and the bonding material for the upper substrate, connection reliability is low between the upper substrate and printed wiring board 10. If the ratio (L2/L1) exceeds 0.7, the amount of the resin layer covering the side surface of the metal post is reduced. Thus, the metal post is more likely to peel off from the pad. Connection reliability is low between the upper substrate and printed wiring board 10. The bonding material for the upper substrate may be formed in the upper substrate. In such a case, a metal post is bonded to the bonding material for the upper substrate formed on the upper substrate, and bonding material 3002 is formed in opening 3001.

Opening 3001 to expose a metal post is preferred to taper from second surface (F2) of the resin layer toward the top surface of a metal post, as shown in FIG. 15. Connection reliability between the upper substrate and the bonding material for the upper substrate, as well as connection reliability between a metal post and the bonding material for the upper substrate, is enhanced. A metal post in the third embodiment is preferred to be such a metal post shown in FIG. 4(B). Since the metal post in FIG. 4(B) is surrounded by resin layer 3000, the metal post is not removed from pad (710FP).

A printed wiring board is manufactured by employing numerous steps, and a significant degree of warping or distortion tends to occur in the printed wiring board. Thus, when a plating process is used in forming metal posts on a printed wiring board, it is thought to be difficult to form metal posts having a uniform height on the printed wiring board.

A printed wiring board according to an embodiment of the present invention narrows the pitch of metal posts for mounting another printed wiring board. A printed wiring board according to an embodiment of the present invention reduces variations in the distance from pads to the top surfaces of metal posts. A method for manufacturing a printed wiring board according to an embodiment of the present invention is a simplified method capable of forming metal posts on pads.

A printed wiring board according to an embodiment of the present invention has an uppermost interlayer resin insulation layer, pads formed on the uppermost interlayer resin insulation layer, and metal posts bonded to the pads through bonding material.

A method for manufacturing a printed wiring board according to an embodiment of the present invention includes the following: forming a metal layer on a support film; forming a bonding layer on the metal layer; forming an etching mask on the bonding layer; etching away the metal layer and the bonding layer exposed from the etching mask; by removing the etching mask, forming on the support film metal posts with attached bonding material that includes the metal layer; preparing a printed wiring board having pads for connection with another printed wiring board; positioning the metal posts with attached bonding material onto the pads in a way that the bonding material faces the pads; bonding the metal posts to the pads through the bonding material; and removing the support film.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
an interlayer resin insulation layer;
a plurality of pads formed on the interlayer resin insulation layer; and
a plurality of metal posts having a plurality of bonding material portions and positioned on the plurality of pads, respectively, such that the metal posts are bonded to the pads through the bonding material portions of the metal posts, respectively.

2. A printed wiring board according to claim 1, wherein the plurality of metal posts is positioned to mount a second printed wiring board onto the interlayer resin insulation layer.

3. A printed wiring board according to claim 1, further comprising:
a solder resist layer formed on the interlayer resin insulation layer such that the solder resist layer has a plurality of openings exposing the plurality of pads,
wherein the plurality of pads has a SMD structure and exposed portions exposed by the openings such that each of the exposed portions is formed to satisfy d1/d2 of 0.6 or more to 0.9 or less where d1 represents a diameter of each of the metal posts and d2 represents a diameter of each of the exposed portions.

4. A printed wiring board according to claim 1, wherein the plurality of pads and the plurality of metal posts are formed to satisfy H/c1 of 5 or more to 20 or less where c1 represents a thickness of the pad and H represents a distance from a surface of a pad facing a metal post to a surface of the metal post at a far end side with respect to the pad.

5. A printed wiring board according to claim 1, wherein the metal posts have first surfaces facing surfaces of the pads at one end sides of the metal posts, second surfaces on opposite end sides with respect to the surfaces facing the pads, and side surfaces between the first surfaces and second surfaces, respectively, and the side surfaces of the metal posts are curved such that the metal posts have narrowed portions formed between the first surfaces and second surfaces, respectively.

6. A printed wiring board according to claim 1, further comprising:
a resin layer formed on the interlayer resin insulation layer such that the plurality of metal posts is formed in the resin layer,
wherein the metal posts have first surfaces facing surfaces of the pads at one end sides of the metal posts, second surfaces on opposite end sides with respect to the surfaces facing the pads, and side surfaces between the first surfaces and second surfaces, respectively, and the resin layer has a plurality of opening portions exposing the second surfaces of the metal posts, respectively.

7. A printed wiring board according to claim 6, wherein the plurality of opening portions of the resin layer is formed such that the opening portions are exposing portions of the side surfaces of the metal posts, respectively, and that the opening portions of the resin layer are tapered from a surface of the resin layer toward the second surfaces of the metal posts.

8. A printed wiring board according to claim 1, wherein the metal posts have first surfaces facing surfaces of the pads at one end sides of the metal posts, and second surfaces on opposite end sides with respect to the surfaces facing the pads, respectively, and the metal posts have metal films formed on the second surfaces of the metal posts, respectively.

9. A printed wiring board according to claim 1, further comprising:
a solder resist layer formed on the interlayer resin insulation layer such that the solder resist layer has a plurality of openings exposing the plurality of pads,
wherein the plurality of pads has a SMD structure and exposed portions exposed by the openings such that each of the exposed portions is formed to satisfy d1/d2 of 0.6 or more to 0.9 or less where d1 represents a diameter of each of the metal posts and d2 represents a diameter of each of the exposed portions, and the plurality of pads and the plurality of metal posts are formed to satisfy H/c1 of 5 or more to 20 or less where c1 represents a thickness of the pad and H represents a distance from a surface of a pad facing a metal post to a surface of the metal post at a far end side with respect to the pad.

10. A printed wiring board according to claim 5, further comprising:
a resin layer formed on the interlayer resin insulation layer such that the plurality of metal posts is formed in the resin layer,
wherein the resin layer has a plurality of opening portions exposing the second surfaces of the metal posts, respectively.

11. A printed wiring board according to claim 1, wherein the plurality of bonding material portions comprises a solder material.

12. A printed wiring board according to claim 1, wherein the plurality of bonding material portions comprises a solder material comprising Sn.

13. A printed wiring board according to claim 1, wherein the plurality of bonding material portions comprises a solder material comprising Sn and Ag.

14. A printed wiring board according to claim 1, wherein the plurality of bonding material portions comprises a solder material, and the plurality of metal posts comprises one of copper and a copper alloy.

15. A printed wiring board according to claim 1, further comprising:
a core substrate; and
a second interlayer resin insulation layer formed on the core substrate,
wherein the interlayer insulation resin layer is formed on the core substrate on an opposite side with respect to the second interlayer resin insulation layer.

16. A method for manufacturing a printed wiring board, comprising:
forming a metal layer on a support film;
forming a bonding layer on the metal layer;
etching the bonding layer such that the bonding layer is selectively removed and a plurality of bonding material portions is formed on the metal layer;
etching the metal layer such that the metal layer is selectively removed and a plurality of metal posts having the bonding material portions respectively is formed on the support film;
positioning the plurality of metal posts having the bonding material portions onto a plurality of pads formed on a printed wiring board such that the plurality of bonding material portions faces the plurality of pads, respectively; and
bonding the plurality of metal posts to the plurality of pads through the bonding material portions of the metal posts.

17. A method for manufacturing a printed wiring board according to claim 16, wherein the etching of the bonding layer and the etching of the metal layer comprise forming an etching mask on the bonding layer and etching the metal layer and the bonding layer such that portions of the metal layer and the bonding layer exposed from the etching mask are selectively removed.

18. A method for manufacturing a printed wiring board according to claim 16, wherein the etching of the bonding layer comprises forming an etching mask on the bonding layer, etching the bonding layer such that a portion of the bonding layer exposed from the etching mask is selectively removed, and removing the etching mask from the plurality of bonding material portions formed on the metal layer, and the etching of the metal layer comprises etching the metal layer such that a portion of the metal layer exposed from the plurality of bonding material portions is selectively removed.

19. A method for manufacturing a printed wiring board according to claim 16, wherein the plurality of pads on the printed wiring board is formed such that the plurality of pads is positioned to connect a second printed wiring board.

20. A method for manufacturing a printed wiring board according to claim 16, further comprising:
removing the support film from the plurality of metal posts.
